(19) United States
(12) Patent Application Publication
(10) Pub. No.: US 2026/0123500 A1
(43) Pub. Date: Apr. 30, 2026

(54) ELECTRONIC COMPONENT MOUNTING DEVICE AND ELECTRONIC COMPONENT MOUNTING METHOD

(71) Applicant: SHINKAWA LTD., Tokyo (JP)

(72) Inventors: Shinichi YOSHIDA, Tokyo (JP); Kohei SEYAMA, Tokyo (JP)

(73) Assignee: SHINKAWA LTD., Tokyo (JP)

(21) Appl. No.: 18/725,132

(22) PCT Filed: Jan. 19, 2022
(86) PCT No.: PCT/JP2022/001776

§ 371 Date: Jun. 28, 2024

(51) Int. Cl. H01L 23/00

(52) U.S. Cl. CPC H10W 72/0711; H10W 72/072; H10W 72/01271; H10W 72/016; H10W 72/07118; H10W 72/07152; H10W 72/07173; H10W 72/07236

(57) ABSTRACT

An electronic component mounting device (1) comprises: an electronic component supply unit (20) that supplies an electronic component having a bump electrode (EB); a transfer stage (31) that accumulates a flux (FX); a mounting stage (41) on which a substrate (BD) is placed; a plurality of heads that can each pick up an electronic component (CP); and a control unit (10) that controls movement of the plurality of heads. The control unit (10) is configured so as to cause each of the plurality of heads to function as a dipping head that dips the bump electrode (EB) of the electronic component (CP) into the flux (FX) accumulated on the transfer stage (31), or as a bonding head that mounts the electronic component (CP) to the substrate (BD) on the mounting stage (41) with the bump electrode (EB) interposed therebetween.

### TECHNICAL FIELD

The present invention relates to an electronic component mounting device and an electronic component mounting method.

### RELATED ART

In the process of mounting electronic components using a flip chip bonding system, generally, the electronic components are soldered to a substrate after flux containing an oxide film remover, a surfactant, etc. is transferred to bump electrodes of the electronic components.

For example, Patent Document 1 discloses an electronic component mounting device, including a tray feeder part in which trays containing a plurality of semiconductor devices as electronic components are set in advance, a transfer stage which has a flux immersion area, a motherboard positioning part which positions and holds a motherboard, and a suction unit which has a suction collet for suctioning and holding the electronic component. In this electronic component mounting device, the suction unit takes out the semiconductor device from the tray using the suction collet, immerses the bump electrode of the electronic component into the flux in the flux immersion area, and then mounts the electronic component on the motherboard in the motherboard positioning part.

### CITATION LIST

### Patent Document

[Patent Document 1] Japanese Patent No. 4,960,160

### SUMMARY OF INVENTION

### Technical Problem

However, according to the electronic component mounting device described in Patent Document 1, the suction collet is at a high temperature in order to solder the bump electrode when mounting the electronic component on the motherboard. The high-temperature suction collet is cooled before immersing the bump electrode into the flux so as to prevent vaporization or deterioration of the flux in the flux immersion area, but this cooling time may affect productivity.

In view of these circumstances, the present invention provides an electronic component mounting device and an electronic component mounting method with improved productivity.

### Solution to Problem

An electronic component mounting device according to one aspect of the present invention includes: an electronic component supply part that supplies an electronic component having a bump electrode; a transfer stage that stores flux; a mounting stage on which a substrate is placed; a plurality of heads that are capable of picking up the electronic component; and a controller that controls operations of the plurality of heads, in which the controller is configured to allocate and enable the plurality of heads to function as a dipping head that immerses the bump electrode of the electronic component into the flux stored in the transfer stage, and as a bonding head that mounts the electronic component to the substrate on the mounting stage via the bump electrode.

According to this aspect, it is not necessary to cool down the head, which is at a high temperature for mounting processing, before immersion processing in order to suppress vaporization or deterioration of the flux. By omitting the cooling time of the head, it becomes possible to shorten the time required for mounting the electronic component to the substrate, making it possible to provide the electronic component mounting device with improved productivity.

In the above aspect, the controller may control a maximum temperature during operation of the dipping head to be lower than a minimum temperature during operation of the bonding head.

According to this aspect, the temperature ranges to be controlled for the dipping head and the bonding head are narrow. Therefore, the time required to change the temperatures of the dipping head and the bonding head can be shortened.

In the above aspect, the controller may control the maximum temperature during operation of the dipping head to be lower than an activation temperature of the flux, and control the minimum temperature during operation of the bonding head to be higher than the activation temperature of the flux.

According to this aspect, the maximum temperature during operation of the dipping head is lower than the activation temperature of the flux, making it possible to suppress the flux from being heated by the head and suppress evaporation or deterioration of the flux. Further, the minimum temperature during operation of the bonding head is higher than the activation temperature of the flux, making it possible to shorten the time required to activate the flux.

In the above aspect, the controller may control a temperature during operation of the dipping head to 20° C. or more and 90° C. or less, and control a temperature during operation of the bonding head to 150° C. or more and 350° C. or less.

According to this aspect, by controlling the dipping head to 20° C. or more, cooling of the flux due to the head can be suppressed, and an increase in the viscosity of the flux can be suppressed. By controlling the dipping head to 90° C. or less, heating of the flux due to the head can be suppressed, and vaporization or deterioration of the flux can be suppressed. By controlling the bonding head to 150° C. or more, the time required to activate the flux can be shortened, and the time required to change the temperature of the head during mounting processing can be shortened. By controlling the bonding head to 350° C. or less, deterioration of the bump electrode due to excessive heating can be suppressed.

In the above aspect, the dipping head may have a cooling mechanism, and the bonding head may have a heating mechanism and a cooling mechanism.

According to this aspect, since the dipping head has a cooling mechanism, an increase in temperature of the dipping head heated by the bonding head can be suppressed. Therefore, vaporization or deterioration of the flux in immersion processing can be suppressed. In addition, since the bonding head has a heating mechanism and a cooling mechanism, it is possible to rapidly melt or solidify only the solder of the electronic component to be mounted without deteriorating the solder of the mounted electronic component due to heat.

In the above aspect, the controller may transport the electronic component from the transfer stage to the mounting stage by the bonding head.

According to this aspect, since the electronic component is consistently held by the bonding head until the electronic component is picked up from the transfer stage and mounted on the substrate, it is possible to reduce the occurrence of defective products due to misalignment of the electronic component.

In the above aspect, the controller may transport the electronic component from the transfer stage to the mounting stage by the dipping head.

According to this aspect, when picking up the electronic component from the transfer stage, heating of the flux due to the head can be suppressed, and vaporization or deterioration of the flux can be suppressed.

In the above aspect, the electronic component mounting device may further include a connecting member that connects the dipping head and the bonding head, in which the dipping head and the bonding head are configured to operate inter-connectedly in a direction along a placement surface of the mounting stage on which the electronic component is placed.

According to this aspect, the configuration can be simplified compared to an electronic component mounting device in which a plurality of heads are configured to be movable separately and independently. Therefore, maintainability is improved and the operating time of the device can be extended.

In the above aspect, the electronic component mounting device may further include a shielding member that inhibits heat exchange between the bonding head and the dipping head.

According to this aspect, an increase in temperature of the dipping head can be suppressed. Therefore, heating of the flux due to the head can be suppressed, and evaporation or deterioration of the flux can be suppressed.

In the above aspect, the dipping head and the bonding head may be configured to be movable separately and independently in a direction along a placement surface of the mounting stage on which the electronic component is placed.

According to this aspect, the immersion processing and the mounting processing can be performed in parallel. Therefore, the productivity can be further improved.

An electronic component mounting method according to another aspect of the present invention is performed using an electronic component mounting device which includes: an electronic component supply part that supplies an electronic component having a bump electrode; a transfer stage that stores flux; a mounting stage on which a substrate is placed; a plurality of heads that are capable of picking up the electronic component; and a controller that controls operations of the plurality of heads. The electronic component mounting method includes: picking up the electronic component from the electronic component supply part by a dipping head among the plurality of heads; immersing the bump electrode of the electronic component into the flux stored in the transfer stage by the dipping head; and mounting the electronic component to the substrate by a bonding head among the plurality of heads.

According to this aspect, it is not necessary to cool down the head, which is at a high temperature for mounting processing, before immersion processing in order to suppress vaporization or deterioration of the flux. By omitting the cooling time of the head, it becomes possible to shorten the time required for mounting the electronic component to the substrate, making it possible to provide the electronic component mounting method with improved productivity.

In the above aspect, the electronic component mounting method may further include: releasing the electronic component from the dipping head on the transfer stage; and picking up the electronic component from the transfer stage by the bonding head.

According to this aspect, since the electronic component is consistently held by the bonding head until the electronic component is picked up from the transfer stage and mounted on the substrate, it is possible to reduce the occurrence of defective products due to misalignment of the electronic component.

In the above aspect, the electronic component mounting method may further include: controlling, by the controller, a maximum temperature during operation of the dipping head to be lower than a minimum temperature during operation of the bonding head.

According to this aspect, the temperature ranges to be controlled for the dipping head and the bonding head are narrow. Therefore, the time required to change the temperatures of the dipping head and the bonding head can be shortened.

### Effects of Invention

According to the present invention, it is possible to provide an electronic component mounting device and an electronic component mounting method with improved productivity.

### BRIEF DESCRIPTION OF DRAWINGS

FIG. 1 is a diagram schematically showing the configuration of the electronic component mounting device according to the first embodiment.

FIG. 2 is a flowchart schematically showing the electronic component mounting method using the electronic component mounting device according to the first embodiment.

FIG. 3 is a diagram schematically showing the state of step S130.

FIG. 4 is a diagram schematically showing the state of step S140.

FIG. 5 is a diagram schematically showing the state of step S160.

FIG. 6 is a diagram schematically showing the state of step S170.

FIG. 7 is a diagram schematically showing the state of step S130.

FIG. 8 is a flowchart schematically showing a modified example of the electronic component mounting method.

FIG. 9 is a diagram schematically showing the configuration of the electronic component mounting device according to the second embodiment.

### DESCRIPTION OF EMBODIMENTS

An embodiment of the present invention will be described hereinafter with reference to the drawings. The drawings of this embodiment are illustrative and the dimensions and shape of each part are schematic, and the technical scope of the present invention should not be construed as being limited to the embodiment.

### First Embodiment

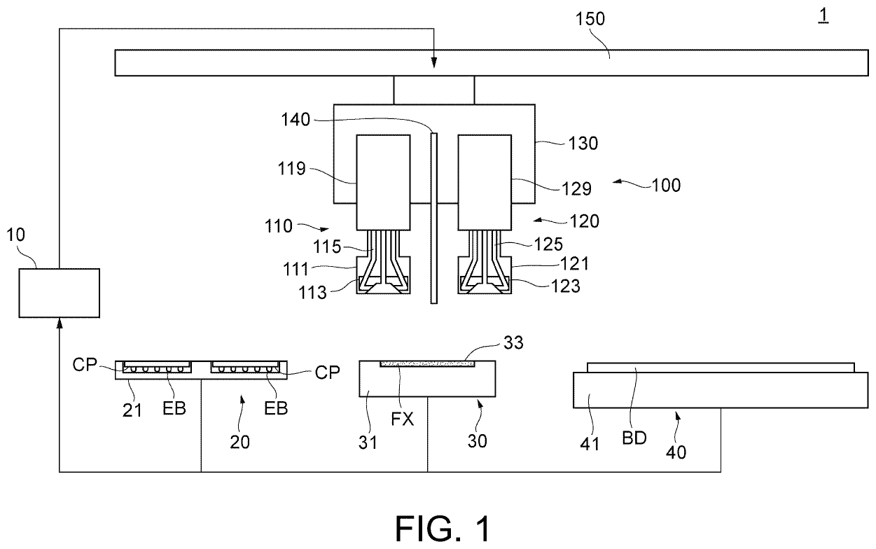

First, the configuration of an electronic component mounting device 1 according to the first embodiment of the present invention will be described with reference to FIG. 1. FIG. 1 is a diagram schematically showing the configuration of the electronic component mounting device according to the first embodiment.

The electronic component mounting device 1 is a flip chip bonder that solders an electronic component CP to a substrate BD. The solder that joins the substrate BD and the electronic component CP is provided, for example, on a bump electrode EB of the electronic component CP. Nevertheless, the solder may be provided on an electrode pad of the substrate BD, or may be provided on both the bump electrode EB and the electrode pad. The electronic component mounting device 1 includes a multi-head unit 100, a controller 10, an electronic component supply unit 20, a transfer unit 30, and a mounting unit 40.

The multi-head unit 100 includes a plurality of heads 110 and 120, a base member 130, a shielding member 140, and a head moving mechanism 150.

The plurality of heads 110 and 120 are configured to be capable of picking up the electronic component CP having the bump electrode EB. The head 110 has a holding tool 111, a heating tool 113, a cooling tool 115, and a lifting mechanism 119. The holding tool 111 is a pair of tweezers that hold the electronic component CP, and is, for example, a suction collet. The heating tool 113 is a heating mechanism that heats the holding tool 111, and is, for example, a ceramic heater. The cooling tool 115 is a cooling mechanism that cools the holding tool 111, and is, for example, a cooling channel, a Peltier element, or the like. The lifting mechanism 119 is a lifting mechanism that raises and lowers the holding tool 111 along a direction (hereinafter referred to as the “vertical direction”) perpendicular to the transfer surface of the transfer unit 30 or the mounting surface of the mounting unit 40, and is, for example, an electric cylinder, an actuator, or the like. The head 120 has a holding tool 121, a heating tool 123, a cooling tool 125, and a lifting mechanism 129. Since the head 120 has the same configuration as the head 110, description of the components of the head 120 will be omitted. The heads 110 and 120 may further include a temperature sensor that detects the temperatures of the heads 110 and 120, a purge gas blowing mechanism that purges oxygen and suppresses oxidation of the electrodes, etc. The purge gas is inert gas that has low reactivity with metal, such as nitrogen gas.

The plurality of heads 110 and 120 are attached to the base member 130. That is, the lifting mechanisms 119 and 129 raise and lower the holding tools 111 and 121 with respect to the base member 130. The base member 130 connects the head 110 and the head 120, and corresponds to an example of the “connecting member” according to the present invention.

The shielding member 140 inhibits heat exchange between the head 110 and the head 120. The shielding member 140 is a plate-shaped member provided between the holding tool 111 and the holding tool 121, and is, for example, a heat insulating plate or a heat shielding plate. The shielding member 140 may include a cooling mechanism.

The head moving mechanism 150 is a moving mechanism that moves the head 110 and the head 120 along a direction (hereinafter referred to as the “horizontal direction”) parallel to the transfer surface of the transfer unit 30 or the mounting surface of the mounting unit 40, and is, for example, an orthogonal robot or a robot manipulator. The head moving mechanism 150 moves the base member 130. Therefore, the head 110 and the head 120 attached to the base member 130 are configured to operate inter-connectedly in the horizontal direction. In addition, the head 110 and the head 120 may be configured to be movable separately and independently along the horizontal direction.

The controller 10 controls the multi-head unit 100. Specifically, the controller 10 enables the head 110 to function as a dipping head that immerses the bump electrode EB of the electronic component CP into the flux FX stored in the transfer unit 30. Further, the controller 10 enables the head 120 to function as a bonding head that mounts the electronic component CP to the substrate BD on the mounting unit 40 via the bump electrode EB. In order for the heads 110 and 120 to share roles in this manner, the controller 10 controls the positions and temperatures of the heads 110 and 120. Further, the controller 10 controls the holding tools 111 and 121 for the heads 110 and 120 to pick up or release the electronic component CP at an appropriate timing. In this specification, the dipping head is a head dedicated to immersion processing, but “dedicated to immersion processing” mentioned here means to exclusively perform operations that belong to the immersion processing without performing operations that belong to the mounting processing among various processes of the immersion processing and the mounting processing, and does not exclude the execution of other processing other than the immersion processing. Besides, similarly, the bonding head is a head dedicated to mounting processing, but “dedicated to mounting processing” mentioned here means to exclusively perform operations that belong to the mounting processing without performing operations that belong to the immersion processing among various processes of the immersion processing and the mounting processing, and does not exclude the execution of other processing other than the mounting processing.

The controller 10 controls the lifting mechanisms 119 and 129 and the head moving mechanism 150 in order to control the positions of the holding tools 111 and 121 of the heads 110 and 120 in the vertical direction and the horizontal direction. The controller 10 controls the position of the holding tool 111 of the head 110 so as to pick up the electronic component CP from the electronic component supply unit 20, transport the electronic component CP from the electronic component supply unit 20 to the transfer unit 30, and immerse the bump electrode EB of the electronic component CP into the flux FX stored in the transfer unit 30. The controller 10 may release the electronic component CP on the transfer unit 30, or may transport the electronic component CP from the transfer unit 30 to the mounting unit 40 and then release the electronic component CP. The controller 10 controls the position of the holding tool 121 of the head 120 so as to mount the electronic component CP on the substrate BD. The controller 10 may enable the head 120 to pick up the electronic component CP from the transfer stage 31 and transport the electronic component CP to the mounting stage 41, or may enable the head 110 to transport the electronic component CP from the transfer stage 31 to the mounting stage 41. In addition, the electronic component mounting device may further include an electronic component delivery part, where the electronic component may be delivered from the holding tool 111 of the head 110 to the holding tool 121 of the head 120.

The controller 10 controls the heating tools 113 and 123 and the cooling tools 115 and 125 of the heads 110 and 120 in order to control the temperatures during operation of the heads 110 and 120 (hereinafter referred to as the “operating temperatures”). The “operating temperatures of the heads 110 and 120” mentioned here refer to the temperatures of the holding tools 111 and 121 in a state where the electronic component mounting device 1 is operating to perform the immersion processing and mounting processing, and a state where the immersion processing and mounting processing can be performed. The controller 10 controls the operating temperature of the head 110 to a temperature range suitable for immersion processing. When the head 120 picks up the electronic component CP from the transfer stage 31, the controller 10 controls the head 120 to be at a temperature lower than the melting point of the solder. Furthermore, when the head 120 mounts the electronic component CP on the substrate BD, the controller 10 controls the head 120 to be at a temperature higher than the melting point of the solder. Hereinafter, the temperature of the head 110 when picking up the electronic component CP from the transfer stage 31 is defined as a “pre-processing temperature”, and the temperature when mounting the electronic component CP on the substrate BD is defined as a “processing temperature.” For example, the minimum temperature of the operating temperature of the head 120 is the pre-processing temperature, and the maximum temperature of the operating temperature of the head 120 is the processing temperature. Thus, by limiting the control range of the operating temperatures of the heads 110 and 120, the time required for the temperature change of the heads 110 and 120 to be completed is shortened.

The controller 10 controls the maximum temperature of the operating temperature of the head 110 to be lower than the minimum temperature of the operating temperature of the head 120. The controller 10 controls the maximum temperature of the operating temperature of the head 110 to be lower than the activation temperature of the flux FX. As an example, the controller 10 preferably controls the operating temperature of the head 110 to 10° C. or more and 120° C. or less, more preferably to 20° C. or more and 90° C. or less, and even more preferably to 20° C. or more and 60° C. or less. Further, the controller 10 controls the minimum temperature of the operating temperature of the head 120 to be lower than the melting point of the solder and the maximum temperature to be higher than the melting point of the solder. The minimum temperature of the operating temperature of the head 120 may be controlled to be higher than the activation temperature of the flux FX, for example. As an example, the controller 10 preferably controls the operating temperature of the head 120 to 100° C. or more and 400° C. or less, more preferably to 150° C. or more and 350° C. or less, and even more preferably to 200° C. or more and 300° C. or less.

Since the controller 10 does not control the head 110 that functions as a dipping head to a high temperature range that allows mounting processing, the heating tool 113 of the head 110 may be omitted. Further, since the controller 10 does not control the head 120 that functions as a bonding head to a low temperature range that allows immersion processing, the cooling tool 125 of the head 120 may be omitted.

The controller 10 may acquire information regarding the operating status of at least one of the electronic component supply unit 20, the transfer unit 30, and the mounting unit 40, and control the multi-head unit 100 based on the information. Furthermore, the controller 10 may control at least one of the electronic component supply unit 20, the transfer unit 30, and the mounting unit 40 based on the operating status of the multi-head unit 100.

In the electronic component supply unit 20, the electronic component CP is supplied to the head 110. The electronic component supply unit 20 corresponds to an example of the “electronic component supply part” according to the present invention. The electronic component supply unit 20 is, for example, a tray feeder that supplies the electronic component CP from a tray 21 in which the electronic components CP are accommodated. In addition, the electronic component supply unit 20 may further include a holding portion that holds the tray 21, a conveyor that transports the tray 21, an orthogonal robot or a robot manipulator, etc. The electronic component supply unit 20 is not limited to the above, and may be a tape feeder, for example.

In the transfer unit 30, the flux FX is transferred to the bump electrode EB of the electronic component CP. The transfer unit 30 includes the transfer stage 31 that stores the flux FX. The flux FX is stored at a uniform depth in the immersion area 33 of the transfer stage 31. In addition, the transfer unit 30 may further include a flux pod that supplies the flux FX to the immersion area 33, a squeegee that levels the surface of the flux FX in the immersion area 33, a temperature adjustment mechanism that adjusts the temperature of the flux FX, an image analysis device that images the surface of the flux FX in the immersion area 33 before or after transfer processing and analyzes the transfer status of the flux FX to the bump electrode EB, etc.

In the mounting unit 40, the electronic component CP is mounted on the substrate BD. The mounting unit 40 includes the mounting stage 41 on which the substrate BD is placed. In addition, the mounting unit 40 may further include a temperature adjustment mechanism that adjusts the temperature of the substrate BD, a cover that covers the substrate BD, a purge gas supply part that purges oxygen in the cover and suppresses oxidation of the electrodes, etc.

The electronic component mounting device 1 may further include a delivery holding portion that temporarily holds the electronic component CP in order to deliver the electronic component CP from the head 110 to the head 120, an image analysis device that images the bump electrode EB after the transfer of the flux FX and analyzes the transfer status of the flux FX to the bump electrode EB, etc.

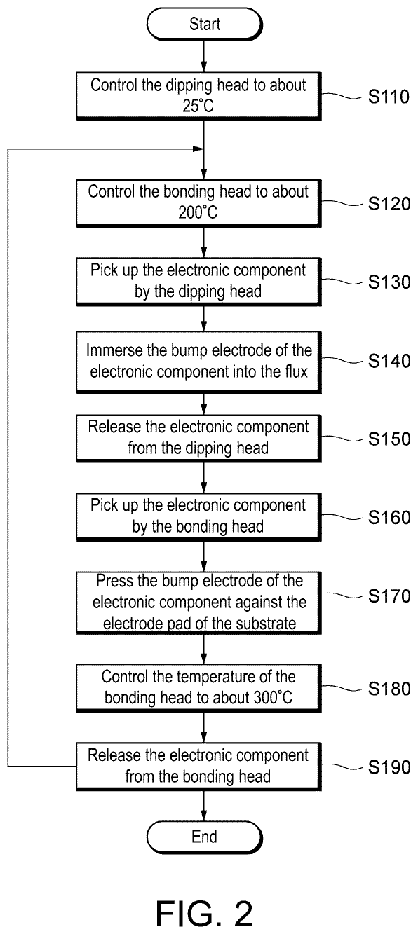

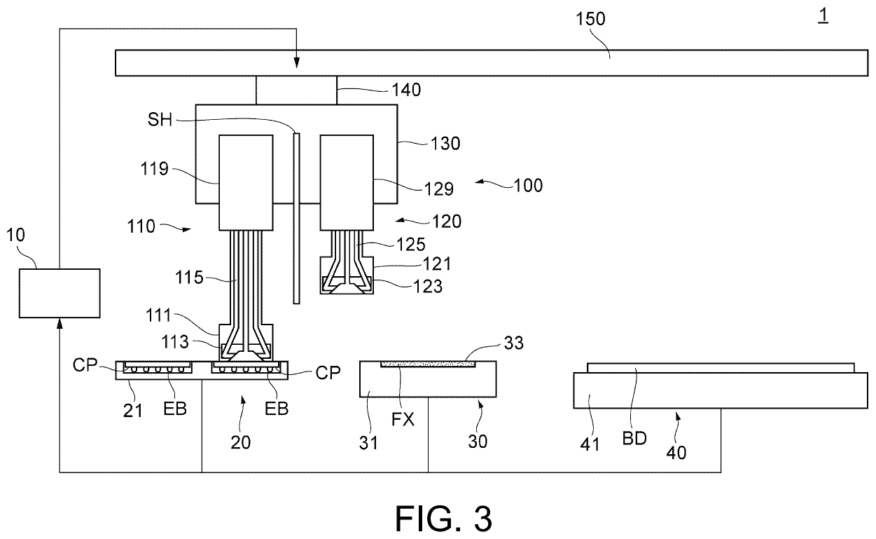

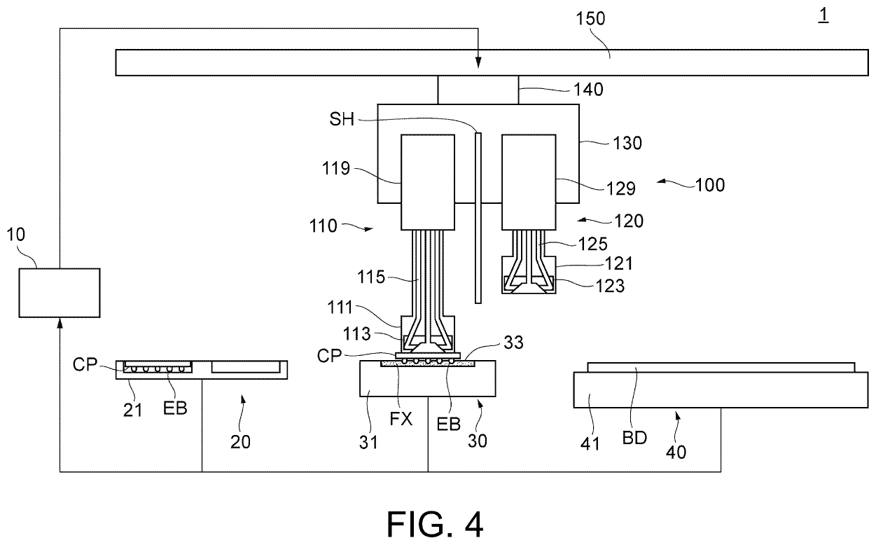

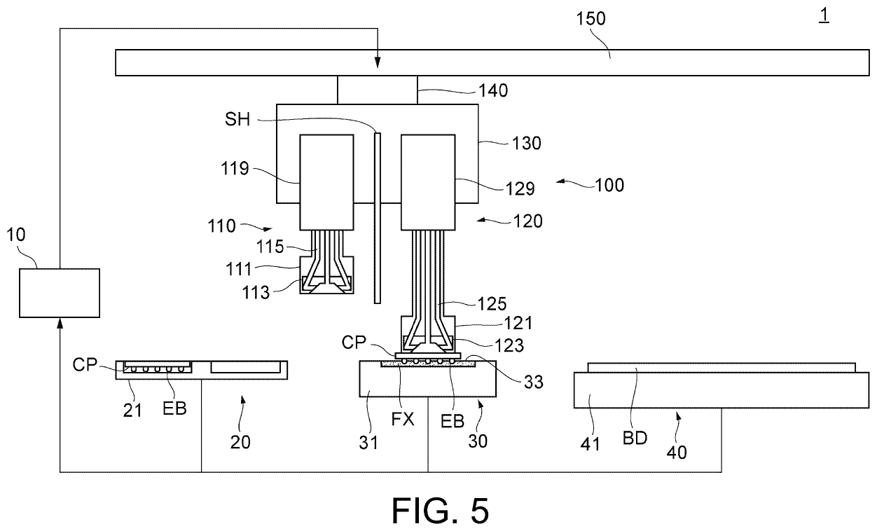

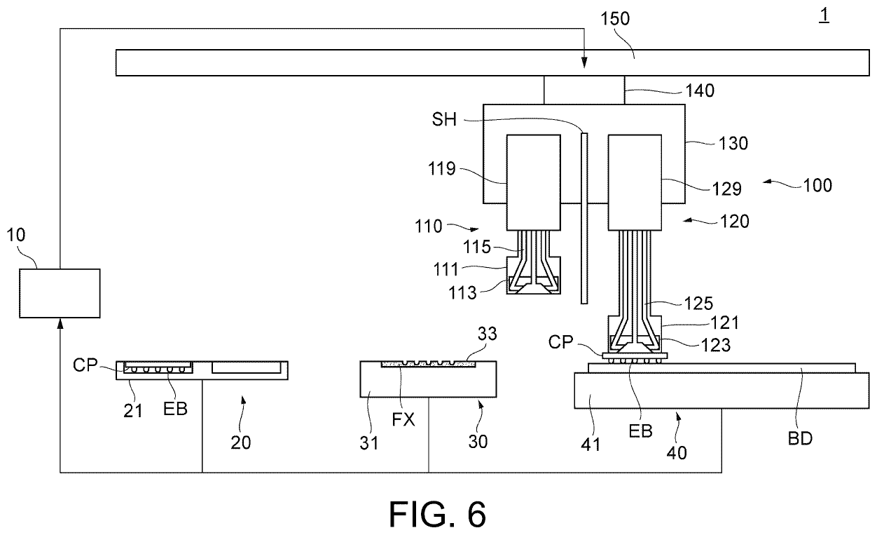

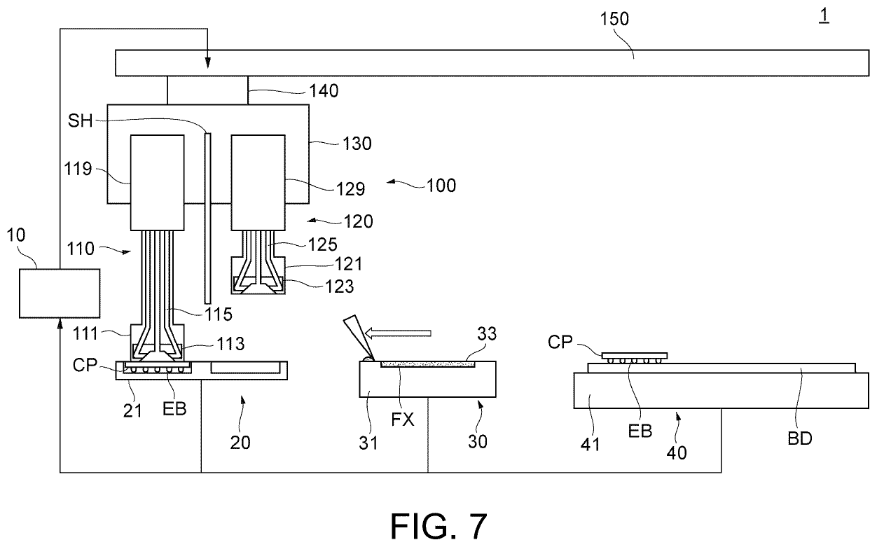

Next, an outline of an electronic component mounting method using the electronic component mounting device 1 will be described with reference to FIG. 2 to FIG. 7. FIG. 2 is a flowchart schematically showing the electronic component mounting method using the electronic component mounting device according to the first embodiment. FIG. 3 is a diagram schematically showing the state of step S130. FIG. 4 is a diagram schematically showing the state of step S140. FIG. 5 is a diagram schematically showing the state of step S160. FIG. 6 is a diagram schematically showing the state of step S170. FIG. 7 is a diagram schematically showing the state of step S130. In the following description, each component of the multi-head unit 100 is controlled by the controller 10. Further, the following illustrates a case where the head 110 functions as a dipping head and the head 120 functions as a bonding head, and hereinafter, the head 110 is also referred to as the “dipping head 110” and the head 120 is also referred to as the “bonding head 120.”

First, the dipping head 110 is controlled to about 25° C. (S110). The operating temperature of the dipping head 110 is not limited to about 25° C. as long as the operating temperature is lower than the activation temperature of the flux FX, and may be controlled to about room temperature, for example. During operation of the electronic component mounting device 1, the temperature of the dipping head 110 varies due to the influence of the bonding head 120, but the temperature is preferably controlled to 20° C. or more and 90° C. or less, and more preferably 20° C. or more and 60° C. or less.

Next, the bonding head 120 is controlled to about 200° C. (S120). At this time, the bonding head 120 is controlled to the pre-processing temperature. That is, the bonding head 120 is controlled to the minimum temperature of the operating temperature. Although the pre-processing temperature is not limited to about 200° C., the pre-processing temperature is preferably set as high as possible as long as the pre-processing temperature is equal to or lower than the melting point of the solder provided on the bump electrode EB and within a temperature range in which vaporization or deterioration of the flux FX stored in the transfer stage 31 is suppressed. When the electronic component CP is picked up by the bonding head 120, which will be described later, the time for the bonding head 120 to approach the flux FX is shorter than the time for the immersion processing. Therefore, even if the bonding head 120 is at a higher temperature of about 200° C. than the dipping head 110, an increase in temperature of the flux FX due to the bonding head 120 can be sufficiently suppressed.

Next, the electronic component CP is picked up by the dipping head 110 (S130). As shown in FIG. 3, the head moving mechanism 150 is controlled to move the base member 130 so that the dipping head 110 overlaps the electronic component CP in the vertical direction. Next, the lifting mechanism 119 is controlled to lower the holding tool 111 vertically downward, and the holding tool 111 is controlled to pick up the electronic component CP. Thereafter, the lifting mechanism 119 is controlled to raise vertically upward the holding tool 111 holding the electronic component CP.

Next, the bump electrode EB of the electronic component CP is immersed into the flux FX (S140). First, the head moving mechanism 150 is controlled to move the base member 130 in the horizontal direction so that the dipping head 110 overlaps the immersion area 33 in the vertical direction. Next, as shown in FIG. 4, the lifting mechanism 119 is controlled to lower the holding tool 111 vertically downward, so that the bump electrode EB of the electronic component CP is immersed into the flux FX.

Next, the electronic component CP is released from the dipping head 110 (S150). The holding tool 111 is controlled to release the electronic component CP, and the lifting mechanism 119 is controlled to raise the holding tool 111 vertically upward.

Next, the electronic component CP is picked up by the bonding head 120 (S160). First, the head moving mechanism 150 is controlled to move the base member 130 in the horizontal direction so that the head 110 overlaps the electronic component CP on the transfer stage 31 in the vertical direction. Next, as shown in FIG. 5, the lifting mechanism 129 is controlled to lower the holding tool 121 vertically downward, and the holding tool 121 is controlled to pick up the electronic component CP. Thereafter, the lifting mechanism 129 is controlled to raise vertically upward the holding tool 121 holding the electronic component CP.

Next, the bump electrode EB of the electronic component CP is pressed against the electrode pad of the substrate BD (S170). First, the head moving mechanism 150 is controlled to move the base member 130 in the horizontal direction so that the bump electrode EB of the electronic component CP overlaps the electrode pad of the substrate BD in the vertical direction. Next, as shown in FIG. 4, the lifting mechanism 129 is controlled to lower the holding tool 121 vertically downward, so that the bump electrode EB of the electronic component CP comes into contact with the electrode pad of the substrate BD. Between step S160 and step S170, the flux FX transferred to the bump electrode EB is heated and activated by the head 120.

Next, the temperature of the bonding head 120 is controlled to about 300° C. (S180). At this time, the temperature of the bonding head 120 is raised from the pre-processing temperature and controlled to the processing temperature. That is, the bonding head 120 is controlled to the maximum temperature of the operating temperature. The processing temperature is not limited to about 300° C., but is appropriately set within a temperature range that is equal to or higher than the melting point of the solder provided on the bump electrode EB and does not deteriorate the solder. In step S180, the solder provided on the bump electrode EB is melted, and the bump electrode EB of the electronic component CP and the electrode pad of the substrate BD are soldered.

Next, the electronic component CP is released from the bonding head 120 (S190). The holding tool 121 is controlled to release the electronic component CP, and the lifting mechanism 129 is controlled to raise the holding tool 121 vertically upward.

Thereafter, the process returns to step S120 again, and the temperature of the bonding head 120 is lowered to the pre-processing temperature. Then, as shown in FIG. 7, step S130 is performed again. During this time, flux FX is added to the immersion area 33 of the transfer stage 31, and the surface of the flux FX supplied to the immersion area 33 is leveled with the squeegee.

In the aspect described above, the controller 10 is configured to allocate and enable the plurality of heads 110 and 120 to function as a dipping head that immerses the bump electrode EB of the electronic component CP into the flux FX stored in the transfer stage 31, and a bonding head that mounts the electronic component CP to the substrate BD on the mounting stage 41 via the bump electrode EB.

According to this, it is not necessary to cool down the head 120, which is at a high temperature for mounting processing, before immersion processing in order to suppress vaporization or deterioration of the flux FX. By omitting the cooling time of the head 120, it becomes possible to shorten the time required for mounting the electronic component CP to the substrate BD, making it possible to provide the electronic component mounting device 1 with improved productivity.

In one aspect, the controller 10 controls the maximum temperature during operation of the dipping head to be lower than the minimum temperature during operation of the bonding head.

According to this, the temperature ranges to be controlled for the dipping head and the bonding head are narrow. Therefore, the time required to change the temperatures of the dipping head and the bonding head can be shortened.

In one aspect, the controller 10 controls the maximum temperature during operation of the dipping head to be lower than the activation temperature of the flux FX, and controls the minimum temperature during operation of the bonding head to be higher than the activation temperature of the flux FX.

According to this, the maximum temperature during operation of the dipping head is lower than the activation temperature of the flux FX, making it possible to suppress the flux FX from being heated by the head 110 and suppress evaporation or deterioration of the flux FX. Further, the minimum temperature during operation of the bonding head is higher than the activation temperature of the flux FX, making it possible to shorten the time required to activate the flux FX.

In one aspect, the controller 10 controls the temperature during operation of the dipping head to 20° C. or more and 90° C. or less, and controls the temperature during operation of the bonding head to 150° C. or more and 350° C. or less.

According to this, by controlling the dipping head to 20° C. or more, cooling of the flux FX due to the head 110 can be suppressed, and an increase in the viscosity of the flux FX can be suppressed. By controlling the dipping head to 90° C. or less, heating of the flux FX due to the head 110 can be suppressed, and vaporization or deterioration of the flux FX can be suppressed. By controlling the bonding head to 150° C. or more, the time required to activate the flux FX can be shortened, and the time required to change the temperature of the head 120 during mounting processing can be shortened. By controlling the bonding head to 350° C. or less, deterioration of the bump electrode EB due to excessive heating can be suppressed.

In one aspect, the dipping head has a cooling mechanism, and the bonding head has a heating mechanism and a cooling mechanism.

According to this, since the dipping head has a cooling mechanism, an increase in temperature of the dipping head heated by the bonding head can be suppressed. Therefore, vaporization or deterioration of the flux FX in immersion processing can be suppressed. In addition, since the bonding head has a heating mechanism and a cooling mechanism, it is possible to rapidly melt or solidify only the solder of the electronic component to be mounted without deteriorating the solder of the mounted electronic component due to heat.

In one aspect, the controller 10 transports the electronic component CP from the transfer stage 31 to the mounting stage 41 by the bonding head.

According to this, since the electronic component CP is consistently held by the bonding head until the electronic component CP is picked up from the transfer stage 31 and mounted on the substrate BD, it is possible to reduce the occurrence of defective products due to misalignment of the electronic component CP.

In one aspect, the electronic component mounting device 1 further includes a connecting member that connects the dipping head and the bonding head, and the dipping head and the bonding head are configured to operate inter-connectedly in a direction along the placement surface of the mounting stage 41 on which the electronic component CP is placed.

According to this, the configuration can be simplified compared to an electronic component mounting device 1 in which a plurality of heads are configured to be movable separately and independently. Therefore, maintainability is improved and the operating time of the device can be extended.

In one aspect, the electronic component mounting device 1 further includes a shielding member 140 that inhibits heat exchange between the bonding head and the dipping head.

According to this, an increase in temperature of the dipping head can be suppressed. Therefore, heating of the flux FX due to the head can be suppressed, and evaporation or deterioration of the flux FX can be suppressed.

Furthermore, the electronic component mounting method using the electronic component mounting device 1 includes picking up the electronic component CP from the electronic component supply part by the dipping head among the plurality of heads 110 and 120, immersing the bump electrode EB of the electronic component CP into the flux FX stored in the transfer stage 31 by the dipping head, and mounting the electronic component CP on the substrate BD by the bonding head among the plurality of heads 110 and 120.

According to this, it is not necessary to cool down the head 120, which is at a high temperature for mounting processing, before immersion processing in order to suppress vaporization or deterioration of the flux FX. By omitting the cooling time of the head 120, it becomes possible to shorten the time required for mounting the electronic component CP to the substrate BD, making it possible to provide the electronic component mounting method with improved productivity.

In one aspect, the electronic component mounting method further includes releasing the electronic component CP from the dipping head on the transfer stage 31, and picking up the electronic component CP from the transfer stage 31 by the bonding head.

According to this, since the electronic component CP is consistently held by the bonding head until the electronic component CP is picked up from the transfer stage 31 and mounted on the substrate BD, it is possible to reduce the occurrence of defective products due to misalignment of the electronic component CP.

In one aspect, the electronic component mounting method further includes controlling, by the controller 10, the maximum temperature during operation of the dipping head to be lower than the minimum temperature during operation of the bonding head.

According to this, the temperature ranges to be controlled for the dipping head and the bonding head are narrow. Therefore, the time required to change the temperatures of the dipping head and the bonding head can be shortened.

Hereinafter, a modified example of the first embodiment and the second embodiment will be described. In addition, configurations the same as or similar to the configuration shown in the first embodiment are denoted by the same or similar reference numerals, and the description thereof is omitted where appropriate. Further, similar effects generated by similar configurations will not be mentioned sequentially.

### Modified Example

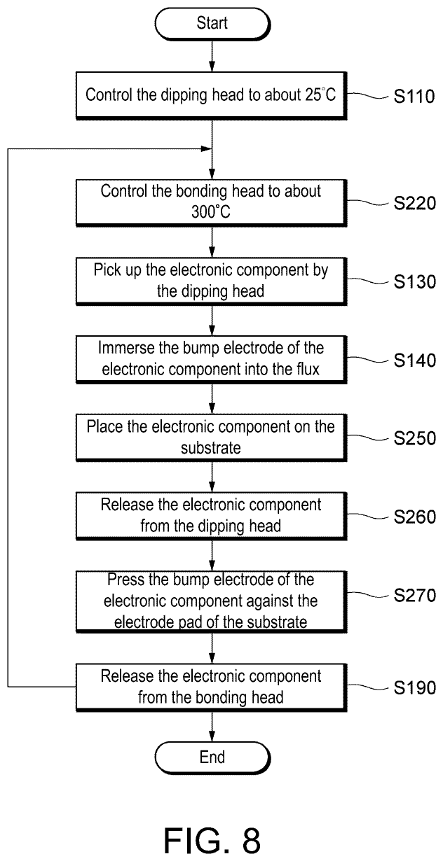

First, a modified example of the electronic component mounting method will be described with reference to FIG. 8. FIG. 8 is a flowchart schematically showing a modified example of the electronic component mounting method.

In this modified example, after step S110 of controlling the dipping head 110 to about 25° C., the bonding head 120 is controlled to 300° C. (S220). That is, the bonding head 120 is controlled to a temperature of about 300° C., which is higher than the melting point of the solder, before coming into contact with the electronic component CP, and is kept at a constant temperature during subsequent soldering. Next, step S130 in which the electronic component CP is picked up by the dipping head 110, and step S140 in which the bump electrode EB of the electronic component CP is immersed into the flux FX are performed.

Next, the electronic component CP is placed on the substrate BD (S250). First, the holding tool 111 is controlled to maintain the state where the dipping head 110 holds the electronic component CP when the bump electrode EB is immersed into the flux FX. Next, the lifting mechanism 119 is controlled to raise the holding tool 111 holding the electronic component CP vertically upward. Next, the head moving mechanism 150 is controlled to move the base member 130 in the horizontal direction so that the bump electrode EB of the electronic component CP overlaps the electrode pad of the substrate BD in the vertical direction. Next, the lifting mechanism 119 is controlled to lower the holding tool 111 vertically downward, so that the bump electrode EB of the electronic component CP comes into contact with the electrode pad of the substrate BD.

Next, the electronic component CP is released from the dipping head 110 (S260). The holding tool 111 is controlled to release the electronic component CP, and the lifting mechanism 119 is controlled to raise the holding tool 111 vertically upward.

Next, the bump electrode EB of the electronic component CP is pressed against the electrode pad of the substrate BD (S270). First, the head moving mechanism 150 is controlled to move the base member 130 in the horizontal direction so that the bonding head 120 overlaps the electronic component CP on the mounting stage 41 in the vertical direction. Next, the lifting mechanism 129 is controlled to lower the holding tool 121 vertically downward, and the electronic component CP is brought into contact with the holding tool 121. Next, the electronic component CP is heated via the holding tool 121 to melt the solder and solder the bump electrode EB and the electrode pad.

Next, the electronic component CP is released from the bonding head 120 (S190), and then the process returns to step S220 again.

Thus, in the electronic component mounting device 1, the controller 10 may enable the dipping head 110 to transport the electronic component CP from the transfer stage 31 to the mounting stage 41.

According to this, when picking up the electronic component CP from the transfer stage 31, heating of the flux FX due to the head 120 can be suppressed, and vaporization or deterioration of the flux FX can be suppressed.

In addition, if the head 110 is used to pick up the electronic component CP from the transfer stage 31, the controller 10 may not enable the head 110 to transport the electronic component CP to the mounting stage 41. For example, in the case where the electronic component mounting device 1 further includes a delivery holding portion that temporarily holds the electronic component CP, the controller 10 may enable the head 110 to transport the electronic component CP from the transfer stage 31 to the delivery holding portion, and then release the electronic component CP from the head 110. Furthermore, the controller 10 may use the head 120 to pick up the electronic component CP from the delivery holding portion and transport the electronic component CP to the mounting stage 41. This also achieves the same effects as this modified example.

### Second Embodiment

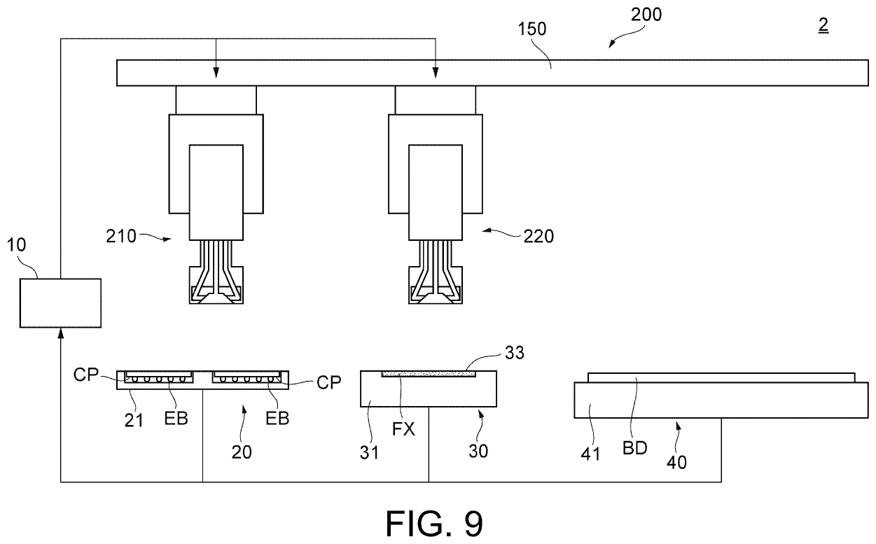

Next, the configuration of an electronic component mounting device 2 according to the second embodiment will be described with reference to FIG. 9. FIG. 9 is a diagram schematically showing the configuration of the electronic component mounting device according to the second embodiment.

In the multi-head unit 200, a plurality of heads 210 and 220 are connected to the head moving mechanism 150 independently of each other. That is, the plurality of heads 210 and 220 are configured to be movable separately and independently in the horizontal direction.

According to this, the immersion processing and the mounting processing can be performed in parallel. Therefore, the productivity can be further improved.

In addition, the multi-head unit 200 may separately include a head moving mechanism for moving the head 210 in the horizontal direction and a head moving mechanism for moving the head 220 in the horizontal direction, instead of the head moving mechanism 150.

As described above, according to one aspect of the present invention, it is possible to provide an electronic component mounting device and an electronic component mounting method with improved productivity.

The above-described embodiments are intended to facilitate understanding of the present invention, and are not intended to limit the present invention. Each element included in the embodiments as well as the arrangement, material, condition, shape, size, etc. thereof are not limited to those illustrated and can be changed as appropriate. Furthermore, it is possible to partially replace or combine the configurations shown in different embodiments.

### REFERENCE SIGNS LIST

1 . . . electronic component mounting device
10 . . . controller
100 . . . multi-head unit
110, 120 . . . head
111, 121 . . . holding tool
113,123 . . . heating tool
115, 125 . . . cooling tool
119, 129 . . . lifting mechanism
130 . . . base member
140 . . . shielding member
150 . . . head moving mechanism
20 . . . electronic component supply unit
21 . . . tray
30 . . . transfer unit
31 . . . transfer stage
33 . . . immersion area
40 . . . mounting unit
41 . . . mounting stage
FX . . . flux
CP . . . electronic component
EB . . . bump electrode
BD . . . substrate

1. An electronic component mounting device, comprising:
an electronic component supply part that supplies an electronic component having a bump electrode;
a transfer stage that stores flux;
a mounting stage on which a substrate is placed;
a connecting member which connects a plurality of heads that are capable of picking up the electronic component at a predetermined interval and which inter-connectedly operates the plurality of heads in a direction along a placement surface of the mounting stage on which the electronic component is placed; and
a controller that controls operations of the plurality of heads,
wherein the controller is configured to allocate and enable the plurality of heads to function as a dipping head that immerses the bump electrode of the electronic component into the flux stored in the transfer stage, and as a bonding head that mounts the electronic component to the substrate on the mounting stage via the bump electrode, and
the controller is configured to pick up the electronic component in a state of being immersed in the flux from the transfer stage by the bonding head by moving the connecting member by the predetermined interval after releasing the electronic component in the state of being immersed in the flux from the dipping head on the transfer stage.

2. The electronic component mounting device according to claim 1, wherein the controller controls a maximum temperature during operation of the dipping head to be lower than a minimum temperature during operation of the bonding head.

3. The electronic component mounting device according to claim 2, wherein the controller controls the maximum temperature during operation of the dipping head to be lower than an activation temperature of the flux, and controls a minimum temperature at which the bonding head picks up the electronic component from the transfer stage to be higher than the activation temperature of the flux.

4. The electronic component mounting device according to claim 2, wherein the controller controls a temperature during operation of the dipping head to 20° C. or more and 90° C. or less, and controls a temperature at which the bonding head picks up the electronic component from the transfer stage to 150° C. or more and 350° C. or less.

5. The electronic component mounting device according to claim 1, wherein the dipping head has a cooling mechanism, and
the bonding head has a heating mechanism and a cooling mechanism.

6. The electronic component mounting device according to claim 1, wherein the controller transports the electronic component from the transfer stage to the mounting stage by the bonding head.

7. The electronic component mounting device according to claim 1, wherein the controller enables the dipping head to transport the electronic component from the transfer stage to the mounting stage.

8. (canceled)

9. The electronic component mounting device according to claim 1, further comprising a shielding member that inhibits heat exchange between the bonding head and the dipping head.

10. The electronic component mounting device according to claim 1, wherein the dipping head and the bonding head are configured to be movable separately and independently in a direction along a placement surface of the mounting stage on which the electronic component is placed.

11. An electronic component mounting method, using an electronic component mounting device which comprises:
an electronic component supply part that supplies an electronic component having a bump electrode;
a transfer stage that stores flux;
a mounting stage on which a substrate is placed;
a connecting member which connects a plurality of heads that are capable of picking up the electronic component at a predetermined interval and which inter-connectedly operates the plurality of heads in a direction along a placement surface of the mounting stage on which the electronic component is placed; and
a controller that controls operations of the plurality of heads,
the electronic component mounting method comprising:
picking up the electronic component from the electronic component supply part by a dipping head among the plurality of heads;
immersing the bump electrode of the electronic component into the flux stored in the transfer stage by the dipping head;
mounting the electronic component to the substrate by a bonding head among the plurality of heads;
moving the connecting member by the predetermined interval after releasing the electronic component from the dipping head on the transfer stage; and
picking up the electronic component from the transfer stage by the bonding head.

12. (canceled)

13. The electronic component mounting method according to claim 11, further comprising:
controlling, by the controller, a maximum temperature during operation of the dipping head to be lower than a minimum temperature during operation of the bonding head.
